(19) United States
(12) Patent Application Publication
(10) Pub. No.: US 2019/0189491 A1
(43) Pub. Date: Jun. 20, 2019

(54) WAFER MOUNTING TABLE

(71) Applicant: NGK INSULATORS, LTD., Nagoya-City (JP)

(72) Inventor: Yuji AKATSUKA, Handa-City (JP)

(73) Assignee: NGK INSULATORS, LTD., Nagoya-City (JP)

(21) Appl. No.: 16/282,833

(22) Filed: Feb. 22, 2019

Related U.S. Application Data
(63) Continuation of application No. PCT/JP2017/029754, filed on Aug. 21, 2017.

(30) Foreign Application Priority Data
Aug. 26, 2016 (JP) 2019-166086

(51) Int. Cl. H01L 21/683; H01L 21/67; B32B 9/00; C23C 16/458

(52) U.S. Cl. CPC H01L 21/6833; H01L 21/6838; B32B 2315/02; B32B 9/005; C23C 16/4586; H01L 21/67098

(57) ABSTRACT

A wafer mounting table includes a ceramic plate having a wafer mounting surface and having at least one electrode; a metal plate arranged on a surface of the ceramic plate opposite to the wafer mounting surface; a threaded terminal made of a low thermal expansion coefficient metal and joined to a recess provided in the surface of the ceramic plate opposite to the wafer mounting surface by a bonding layer including ceramic fine particles and a hard solder; and a screw member inserted into a through hole penetrating the metal plate and screwed to the threaded terminal to fasten the ceramic plate and the metal plate together, wherein in a state in which the threaded terminal and the screw member are screwed together, a play is provided in a direction in which the metal plate is displaced relative to the ceramic plate due to the difference in thermal expansion.

### BACKGROUND OF THE INVENTION

### 1. Field of the Invention

The present invention relates to a wafer mounting table.

### 2. Description of the Related Art

As a wafer mounting table for a semiconductor manufacturing apparatus, there has been known one formed by joining a ceramic plate having a built-in electrostatic electrode and a metal plate for cooling the ceramic plate. For example, in PTL 1, a resin adhesive layer capable of absorbing the difference in thermal expansion between a ceramic plate and a metal plate is used when joining the ceramic plate and the metal plate.

### CITATION LIST

### Patent Literature

PTL 1: JP 2014-132560

### SUMMARY OF THE INVENTION

However, when a resin adhesive layer is used, there is a problem that use in a high-temperature range is limited or corrosion is caused by process gas. On the other hand, although it is conceivable to fasten the ceramic plate and the metal plate together directly with screws, there is a risk that cracks may be generated in the ceramic plate due to the fastening force at the time of fastening or the stress caused by the difference in thermal expansion.

The present invention has been made to solve such problems, and its main object is to provide a wafer mounting table that can withstand use in a high-temperature range.

According to the present invention, there is provided a wafer mounting table including:

a ceramic plate having a wafer mounting surface and having at least one of an electrostatic electrode and a heater electrode built therein;

a metal plate arranged on a surface of the ceramic plate opposite to the wafer mounting surface;

a threaded terminal made of a low thermal expansion coefficient metal and joined to a recess provided in the surface of the ceramic plate opposite to the wafer mounting surface by a bonding layer including ceramic fine particles and a hard solder; and

a screw member inserted into a through hole penetrating the metal plate and screwed to the threaded terminal to fasten the ceramic plate and the metal plate together,

wherein in a state in which the threaded terminal and the screw member are screwed together, a play is provided in a direction in which the metal plate is displaced relative to the ceramic plate due to the difference in thermal expansion.

In this wafer mounting table, a threaded terminal joined to a recess provided in the surface of the ceramic plate opposite to the wafer mounting surface and a screw member inserted into a through hole having a step penetrating the metal plate are screwed together, and the ceramic plate and the metal plate are fastened together. Since the threaded terminal is made of a metal having a low thermal expansion coefficient, the thermal expansion coefficient thereof is close to that of the ceramic plate. Therefore, even in the case of repeated use at a high temperature and a low temperature, the ceramic plate and the threaded terminal are less liable to suffer cracking or the like due to thermal stress caused by the difference in thermal expansion coefficient. If a thread that can be screwed with the screw member is directly provided in the recess of the ceramic plate, the ceramic plate may be broken when screwed with the screw member. However, in this case, since the screw member is screwed to the threaded terminal joined to the ceramic plate, there is no such risk. Furthermore, since the threaded terminal is joined to the recess of the ceramic plate by the bonding layer including ceramic fine particles and a hard solder, the bonding strength between the threaded terminal and the ceramic plate is sufficiently high. Further, in a state in which the threaded terminal and the screw member are screwed together, a play p is provided in a direction in which the metal plate is displaced relative to the ceramic plate due to the difference in thermal expansion. Therefore, even in the case of repeated use at a high temperature and a low temperature, thermal stress caused by the difference in thermal expansion between the metal plate and the ceramic plate can be absorbed by this play. As described above, the wafer mounting table of the present invention can withstand use in a high-temperature range.

In this description, low thermal expansion coefficient means that the coefficient of linear thermal expansion (CTE) is c×10⁻⁶/K (c is 3 or more and less than 10) at 0 to 300° C.

The wafer mounting table of the present invention may include a non-adhesive heat conductive sheet between the ceramic plate and the metal plate. In the wafer mounting table of the present invention, since the ceramic plate and the metal plate are fastened together by screwing the threaded terminal and the screw member together, the heat conductive sheet between the ceramic plate and the metal plate is not required to have adhesiveness. Therefore, the degree of freedom in selecting the heat conductive sheet is increased. For example, a high thermal conductivity sheet may be employed to enhance the heat removal performance from the ceramic plate to the metal plate, and a low thermal conductivity sheet may be employed to suppress the heat removal performance.

In the wafer mounting table of the present invention, the ceramic fine particles may be fine particles whose surfaces are coated with a metal, and the hard solder may contain Au, Ag, Cu, Pd, Al or Ni as a base metal. This makes it easy for the molten hard solder to uniformly spread on the surfaces coated with the metal of the ceramic fine particles when the bonding layer is formed. Therefore, the bonding strength between the threaded terminal and the ceramic plate becomes higher.

In the wafer mounting table of the present invention, the ceramic plate is preferably made of AlN or Al₂O₃. The metal plate is preferably made of Al or Al alloy. The low thermal expansion coefficient metal is preferably one kind selected from the group consisting of Mo, W, Ta, Nb and Ti, an alloy containing the one kind of metal (for example, W—Cu or Mo—Cu), or Kovar (FeNiCo alloy).

In the wafer mounting table of the present invention, the coefficient of linear thermal expansion of the threaded terminal is preferably within a range of ±25% of the coefficient of linear thermal expansion of the ceramic plate. This makes it easier to withstand use in a high-temperature range.

### BRIEF DESCRIPTION OF THE DRAWINGS

FIG. 1 is an explanatory view schematically showing the configuration of a plasma processing apparatus 10.

FIG. 2 is a sectional view of an electrostatic chuck heater 20.

FIG. 3 is an enlarged view of a part surrounded by a circle in two-dot chain line of FIG. 2.

FIGS. 4A and 4B are explanatory views showing the step of joining a recess 28 and a female threaded terminal 30.

FIG. 5 is a bottom view of the electrostatic chuck heater 20.

FIG. 6 is a partially enlarged view of another embodiment.

FIG. 7 is a partially enlarged view of another embodiment.

FIG. 8 is a plan view of a heat conductive sheet 36 having a trimming region 36b.

### DETAILED DESCRIPTION OF THE INVENTION

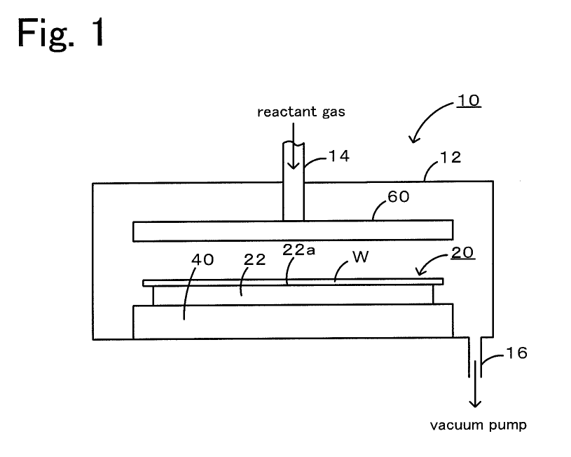

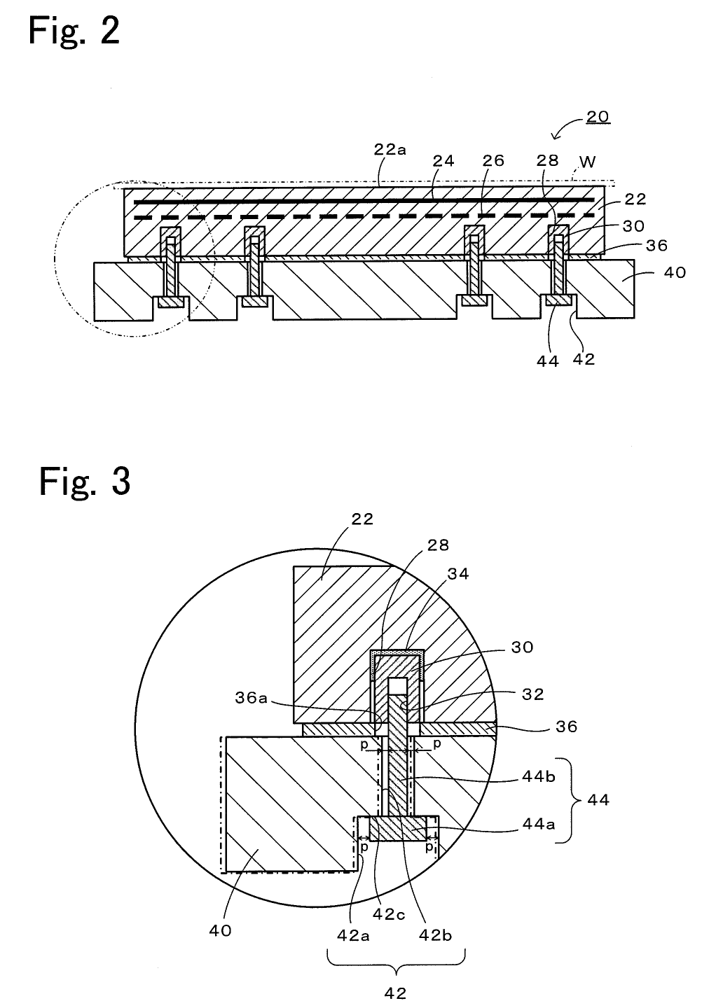

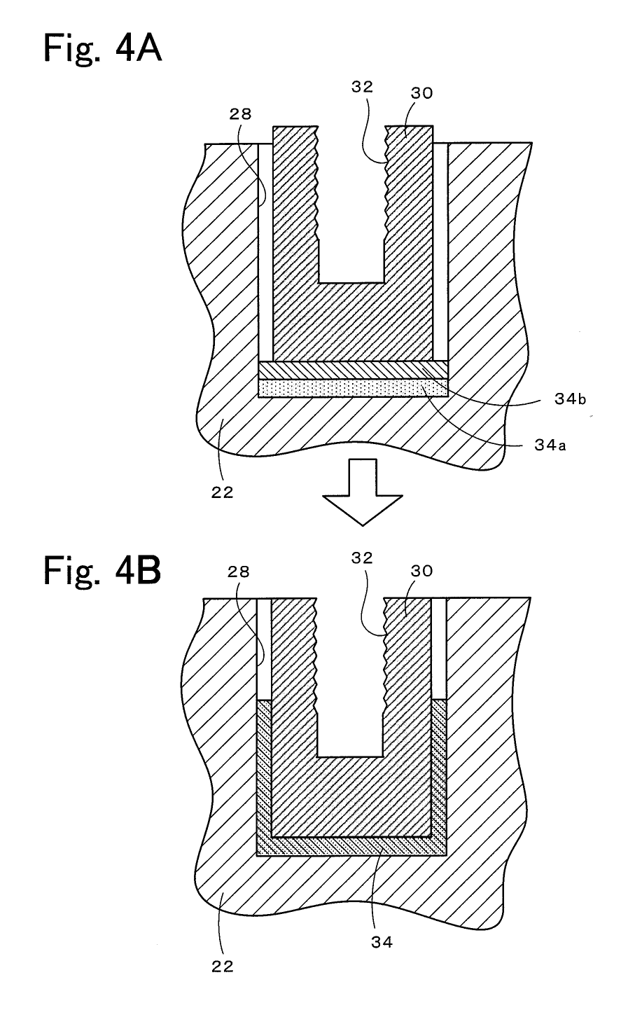

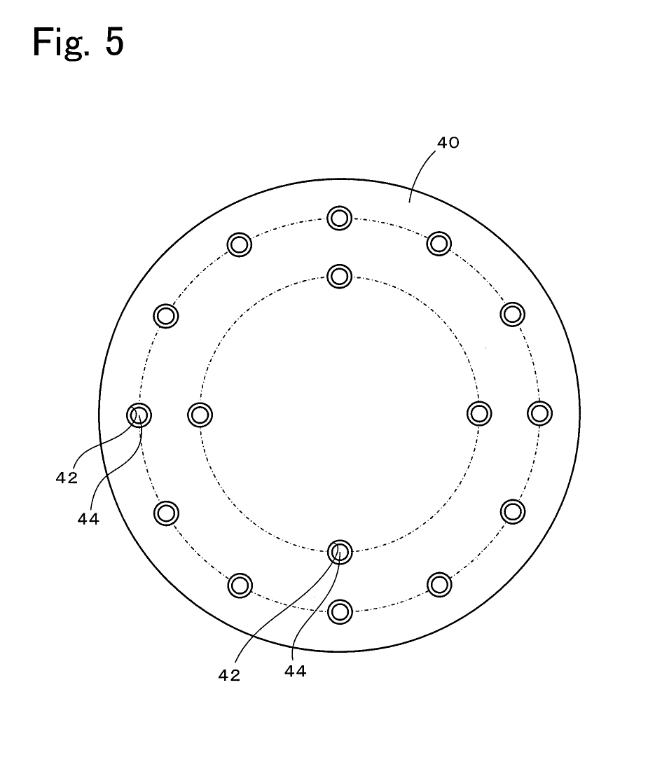

An electrostatic chuck heater 20 that is a preferred embodiment of the wafer mounting table of the present invention will now be described. FIG. 1 is an explanatory view schematically showing the configuration of a plasma processing apparatus 10 including the electrostatic chuck heater 20, FIG. 2 is a sectional view of the electrostatic chuck heater 20, FIG. 3 is an enlarged view of a part surrounded by a circle in two-dot chain line of FIG. 2, FIGS. 4A and 4B are explanatory views showing the step of joining a recess 28 and a female threaded terminal 30 together, and FIG. 5 is a bottom view of the electrostatic chuck heater 20. The vertical relationships in FIGS. 4A and 4B are opposite to that in FIG. 2.

As shown in FIG. 1, the plasma processing apparatus 10 includes a metal (for example, aluminum alloy) vacuum chamber 12, the internal pressure of which can be controlled, and an electrostatic chuck heater 20 and an upper electrode 60 for generating plasma that are arranged in the vacuum chamber 12. Numerous small holes for supplying reactant gas to the wafer mounting surface are formed in a surface of the upper electrode 60 that faces the electrostatic chuck heater 20. The vacuum chamber 12 is configured so that reactant gas can be introduced into the upper electrode 60 through a reactant gas introduction path 14, and the internal pressure of the vacuum chamber 12 can be reduced to a predetermined degree of vacuum using a vacuum pump connected to an evacuation path 16.

The electrostatic chuck heater 20 includes an electrostatic chuck 22 capable of sucking a wafer W to be subjected to plasma processing onto a wafer mounting surface 22a, and a cooling plate 40 arranged on the lower surface of the electrostatic chuck 22. Numerous protrusions (not shown) having a height of several gm are formed over the entire surface of the wafer mounting surface 22a. The wafer W mounted on the wafer mounting surface 22a is supported on the upper surfaces of these protrusions. He gas is introduced to several of flat parts of the wafer mounting surface 22a where no protrusions are provided.

The electrostatic chuck 22 is a ceramic plate (for example, made of AlN or Al₂O₃) having an outer diameter smaller than the outer diameter of the wafer W. As shown in FIG. 2, an electrostatic electrode 24 and a heater electrode 26 are buried in the electrostatic chuck 22. The electrostatic electrode 24 is a planar electrode to which a DC voltage can be applied. When a DC voltage is applied to the electrostatic electrode 24, the wafer W is sucked and fixed to the wafer mounting surface 22a by a Coulomb force or a Johnsen-Rahbek force. When the application of the DC voltage is stopped, the wafer W is released from being sucked and fixed to the wafer mounting surface 22a. The heater electrode 26 is a resistance wire patterned over the entire surface in a single stroke manner. When a voltage is applied to the heater electrode 26, the heater electrode 26 generates heat and heats the entire surface of the wafer mounting surface 22a. The heater electrode 26 has a coil shape, a ribbon shape, a mesh shape, a plate shape or a film shape, and is formed of, for example, W, WC, Mo, or the like. Voltage can be applied to the electrostatic electrode 24 and the heater electrode 26 by a power supply member (not shown) inserted into the cooling plate 40 and the electrostatic chuck 22.

Recesses 28 are provided in a surface of the electrostatic chuck 22 opposite to the wafer mounting surface 22a. The recesses 28 are, for example, non-through holes. Female threaded terminals 30 are inserted into the recesses 28. As shown in FIG. 3, the female threaded terminal 30 and the recess 28 are joined by a bonding layer 34. The female threaded terminal 30 is a bottomed cylindrical member made of a low thermal expansion coefficient metal, and the cylindrical part is provided with a female thread 32. Low thermal expansion coefficient means that the coefficient of linear thermal expansion (CTE) is c×10⁻⁶/K (c is 3 or more and less than 10, preferably 5 or more and 7 or less) at 0 to 300° C. Examples of the low thermal expansion coefficient metal include high melting point metals such as Mo, W, Ta, Nb, and Ti, alloys whose main component is one of these high melting point metals (for example, W—Cu or Mo—Cu), and Kovar (FeNiCo alloy). The CTE of the low thermal expansion coefficient metal is preferably the same as the CTE of the ceramic used for the electrostatic chuck 22, and preferably within the range of ±25% of the CTE of the ceramic. This makes it easier to withstand use in a high-temperature range. For example, when the ceramic used for the electrostatic chuck 22 is AlN (4.6×10⁻⁶/K (40 to 400° C.)), Mo or W is preferably selected as the low thermal expansion coefficient metal. When the ceramic used for the electrostatic chuck 22 is Al₂O₃ (7.2×10⁻⁶/K (40 to 400° C.)), Mo is preferably selected as the low thermal expansion coefficient metal.

The bonding layer 34 includes ceramic fine particles and a hard solder. Examples of the ceramic fine particles include Al₂O₃ fine particles and AlN fine particles. The surfaces of the ceramic fine particles are preferably coated with a metal (for example, Ni) by plating or sputtering. The average particle size of the ceramic fine particles is not particularly limited, but is, for example, from 10 μm to 500 μm, preferably from 20 μm to 100 μm. When the average particle size is smaller than the lower limit, it is not preferable because the adhesion of the bonding layer 34 may not be sufficiently obtained. When the average particle size exceeds the upper limit, it is not preferable because the inhomogeneity becomes significant and the heat resistance characteristics, etc. may be deteriorated. Examples of hard solders include solders based on metals such as Au, Ag, Cu, Pd, Al, and Ni. When the ambient operating temperature of the electrostatic chuck heater 20 is 500° C. or less, an Al-based solder such as BA4004 (Al-10Si-1.5Mg) is preferably used as the hard solder. When the ambient operating temperature of the electrostatic chuck heater 20 is 500° C. or more, Au, BAu-4 (Au-18Ni), and BAg-8 (Ag-28Cu) are preferably used as the hard solder. The packing density of the ceramic fine particles in the hard solder is preferably from 30 to 90%, more preferably from 40 to 70% by volume. Increasing the packing density of the ceramic fine particles is advantageous in lowering the coefficient of linear thermal expansion of the bonding layer 34, but increasing the packing density too high is not preferable because it may cause deterioration of the bonding strength. If the packing density of the ceramic fine particles is made too low, the coefficient of linear thermal expansion of the bonding layer 34 may not be sufficiently lowered, and care should be taken in this respect. Since the ceramic fine particles are coated with metal, the ceramic fine particles have good wettability with the hard solder. As a method of coating ceramic fine particles with metal, sputtering or plating can be used.

As an example of a method of inserting and joining the female threaded terminal 30 to the recess 28 of the electrostatic chuck 22, first, as shown in FIG. 4A, ceramic fine particles 34a are spread almost evenly on the surface of the recess 28, a hard solder 34b in the form of a plate or a powder is placed so as to cover at least a part of the layer of the ceramic fine particles 34a, and thereafter the female threaded terminal 30 is inserted. Next, in a state in which the female threaded terminal 30 is pressed against the recess 28, heating to a predetermined temperature is performed to cause the hard solder 34b to melt and penetrate into the layer of the ceramic fine particles 34a. When ceramic fine particles 34a whose surfaces are coated with a metal are used, the molten hard solder 34b easily uniformly spreads on the surfaces coated with the metal of the ceramic fine particles 34a, and therefore easily penetrate into the layer of the ceramic fine particles 34a. Since it is necessary for the hard solder 34b used to melt and penetrate into the layer of the ceramic fine particles 34a, a temperature 10 to 150° C. higher than the melting point of the hard solder 34b, and preferably 10 to 50° C. higher than the melting point of the hard solder 34b, is suitable as a temperature for melting the hard solder 34b. Thereafter, cooling is performed. The cooling time may be set appropriately, for example, in the range of 1 hour to 10 hours. In this way, as shown in FIG. 4B, the recess 28 of the electrostatic chuck 22 and the female threaded terminal 30 are firmly bonded via the bonding layer 34.

The cooling plate 40 is a member made of metal (for example, Al or Al alloy). The cooling plate 40 has a cooling medium path through which a cooling medium (for example, water) cooled by an external cooling unit (not shown) circulates. Through holes 42 each having a step 42c are provided at positions of the cooling plate 40 facing the recesses 28 of the electrostatic chuck 22. As shown in FIG. 5, when the circular cooling plate 40 is viewed from the lower surface, the through holes 42 include a plurality of (here four) through holes provided at equal intervals along a small circle and a plurality of (here 12) through holes provided at equal intervals along a large circle. The through hole 42 has a large diameter portion 42a on the side opposite to the electrostatic chuck 22 and a small diameter portion 42b on the side of the electrostatic chuck 22 with the step 42c as a boundary. A male screw 44 is inserted into the through hole 42. The male screw 44 may be made of, for example, stainless steel. The screw shank 44b of the male screw 44 is screwed to the female thread 32 of the female threaded terminal 30 with the screw head 44a in contact with the step 42c of the through hole 42. That is, the male screw 44 is screwed to the female thread 32 of the female threaded terminal 30 such that the distance between the step 42c of the cooling plate 40 and the female threaded terminal 30 of the electrostatic chuck 22 decreases. In this manner, the electrostatic chuck 22 and the cooling plate 40 are fastened together by the female threaded terminals 30 and the male screws 44. The diameter of the screw head 44a is smaller than that of the large diameter portion of the through hole 42, and the diameter of the screw shank 44b is smaller than that of the small diameter portion of the through hole 42. Therefore, in a state in which the female threaded terminal 30 and the male screw 44 are screwed together, a play p (horizontal gap in FIG. 3) is provided in a direction in which the cooling plate 40 is displaced relative to the electrostatic chuck 22 due to the difference in thermal expansion.

The heat conductive sheet 36 is a layer made of a resin having heat resistance and insulation properties, is disposed between the electrostatic chuck 22 and the cooling plate 40, and serves to transfer the heat of the electrostatic chuck 22 to the cooling plate 40. The heat conductive sheet 36 does not have adhesiveness. Through holes 36a are formed at positions of the heat conductive sheet 36 facing the recesses 28 of the electrostatic chuck 22. When it is desired to efficiently remove heat from the electrostatic chuck 22 to the cooling plate 40, a sheet having a high thermal conductivity is used as the heat conductive sheet 36. On the other hand, when it is desired to suppress heat removal from the electrostatic chuck 22 to the cooling plate 40, a sheet having a low thermal conductivity is used as the heat conduction sheet 36. Examples of the heat conductive sheet 36 include a polyimide sheet (for example, a Kapton sheet (Kapton is a registered trademark) or a Vespel sheet (Vespel is a registered trademark)) and a PEEK sheet. Since such a resin sheet having high heat resistance is usually hard, when the resin sheet is used as a layer for bonding the electrostatic chuck 22 and the cooling plate 40, there is a possibility that the sheet may be peeled off or damaged due to the difference in thermal expansion between the electrostatic chuck 22 and the cooling plate 40. In the present embodiment, since such a sheet is used as the heat conductive sheet 36 in the non-bonded state, there is no possibility that such a problem will occur.

Next, an example of the use of the plasma processing apparatus 10 thus configured will be described. First, in a state in which the electrostatic chuck heater 20 is installed in the vacuum chamber 12, a wafer W is mounted on the wafer mounting surface 22a of the electrostatic chuck 22. Then, the vacuum chamber 12 is reduced in pressure by a vacuum pump and adjusted to a predetermined degree of vacuum, and a DC voltage is applied to the electrostatic electrode 24 of the electrostatic chuck 22 to generate a Coulomb force or a Johnsen-Rahbek force, and the wafer W is sucked and fixed to the wafer mounting surface 22a of the electrostatic chuck 22. He gas is introduced between the wafer W supported by protrusions (not shown) on the wafer mounting surface 22a and the wafer mounting surface 22a. Next, the inside of the vacuum chamber 12 is set to a reactant gas atmosphere at a predetermined pressure (for example, several tens to several hundreds Pa), and in this state, a high-frequency voltage is applied between the upper electrode 60 and the electrostatic electrode 24 of the electrostatic chuck 22 in the vacuum chamber 12 to generate a plasma. Although both a DC voltage for generating an electrostatic force and a high-frequency voltage are applied to the electrostatic electrode 24, the high-frequency voltage may be applied to the cooling plate 40 instead of the electrostatic electrode 24. Then, the surface of the wafer W is etched by the generated plasma. The temperature of the wafer W is controlled to be a predetermined target temperature.

Here, the relationship between the components of the present embodiment and the components of the present invention will be clarified. The electrostatic chuck heater 20 of the present embodiment corresponds to the wafer mounting table of the present invention, the electrostatic chuck 22 corresponds to the ceramic plate, the cooling plate 40 corresponds to the metal plate, the female threaded terminal 30 corresponds to the threaded terminal, and the male screw 44 corresponds to the screw member.

In the above-described electrostatic chuck heater 20, since the female threaded terminal 30 is made of a low thermal expansion coefficient metal, the thermal expansion coefficient thereof is close to that of ceramic used in the electrostatic chuck 22. Therefore, even in the case of repeated use at a high temperature and a low temperature, the electrostatic chuck 22 and the female threaded terminal 30 are less liable to suffer cracking or the like due to thermal stress caused by the difference in thermal expansion coefficient. If a female thread that can be screwed with the male screw 44 is directly provided in the recess 28 of the electrostatic chuck 22, the electrostatic chuck 22 may be broken when screwed with the male screw 44. However, in this case, since the male screw 44 is screwed to the female threaded terminal 30 joined to the electrostatic chuck 22, there is no such risk. Furthermore, since the female threaded terminal 30 is joined to the recess 28 of the electrostatic chuck 22 by the bonding layer 34 including ceramic fine particles and a hard solder, the bonding between the female threaded terminal 30 and the electrostatic chuck 22 is as sufficiently high as 100 kgf or more in terms of tensile strength (for this kind of bonding layer 34, see Japanese Patent No. 3315919, Japanese Patent No. 3792440 and Japanese Patent No. 3967278). Further, in a state in which the female threaded terminal 30 and the male screw 44 are screwed together, a play p is provided in a direction in which the cooling plate 40 is displaced relative to the electrostatic chuck 22 due to the difference in thermal expansion. Therefore, even in the case of repeated use at a high temperature and a low temperature, displacement due to the difference in thermal expansion between the cooling plate 40 and the electrostatic chuck 22 can be absorbed by this play p. For example, the one-dot chain line in FIG. 3 shows a state where the cooling plate 40 has expanded relative to the electrostatic chuck 22 due to the difference in thermal expansion. When the cooling plate 40 expands and contracts relative to the electrostatic chuck 22, the screw head 44a can slide on the surface of the step 42c, and the screw shank 44b can move in the small diameter portion 42b of the through hole 42 in the left-right direction in FIG. 3, so that the electrostatic chuck 22 is not easily broken. As described above, the electrostatic chuck heater 20 can withstand use in a high-temperature range. Further, by joining the female threaded terminal 30 into the recess 28, it is possible to prevent the male screw 44 from being exposed to the process atmosphere and being corroded.

The electrostatic chuck heater 20 includes a non-adhesive heat conductive sheet 36 between the electrostatic chuck 22 and the cooling plate 40. In this embodiment, since the electrostatic chuck 22 and the cooling plate 40 are fastened together by screwing the female threaded terminal 30 and the male screw 44 together, the heat conductive sheet 36 is not required to have adhesiveness. Therefore, the degree of freedom in selecting the heat conductive sheet 36 is increased. For example, a high thermal conductivity sheet may be employed to enhance the heat removal performance from the electrostatic chuck 22 to the cooling plate 40, and a low thermal conductivity sheet may be employed to suppress the heat removal performance. The heat conductive sheet 36 also serves to prevent the female threaded terminals 30 and male screws 44 from being exposed to the process atmosphere (plasma or the like).

Further, the ceramic fine particles constituting the bonding layer 34 are fine particles whose surfaces are coated with a metal, and the hard solder contains Au, Ag, Cu, Pd, Al or Ni as a base metal. Therefore, the bonding strength between the female threaded terminal 30 and the electrostatic chuck 22 becomes higher.

It should be noted that the present invention is not limited to the above-described embodiment at all, and it is needless to say that the present invention can be implemented in various embodiments without departing from the technical scope of the present invention.

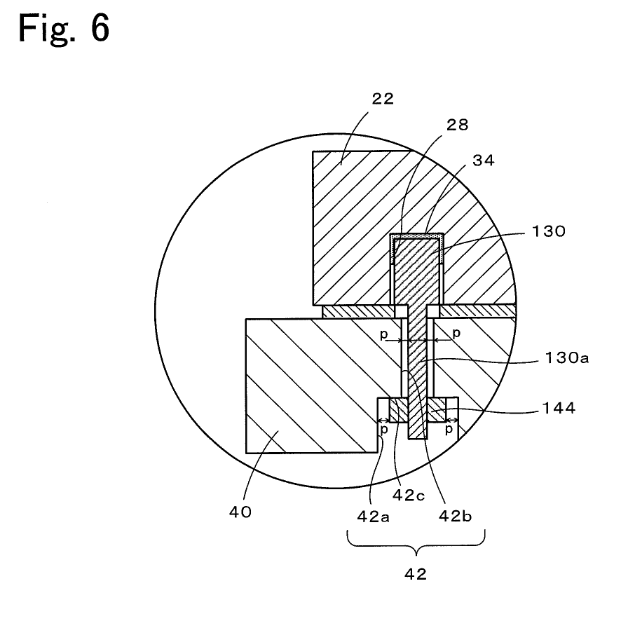

For example, in the above-described embodiment, the female threaded terminal 30 and the male screw 44 are exemplified, but the present invention is not particularly limited thereto. For example, as shown in FIG. 6, a male threaded terminal 130 may be joined to the recess 28 of the electrostatic chuck 22 via the bonding layer 34, and fastened with a nut (female screw) 144 such that the distance between the male threaded terminal 130 and the step 42c of the cooling plate 40 decreases. In this case, the diameter of the nut 144 is smaller than that of the large diameter portion 42a of the through hole 42, and the diameter of the male threaded portion 130a of the male threaded terminal 130 is smaller than that of the small diameter portion 42b of the through hole 42. Therefore, in a state in which the male threaded terminal 130 and the nut 144 are screwed together, a play is provided in a direction in which the cooling plate 40 is displaced relative to the electrostatic chuck 22 due to the difference in thermal expansion. Therefore, according to the configuration of FIG. 6, the same effect as in the above-described embodiment can be obtained.

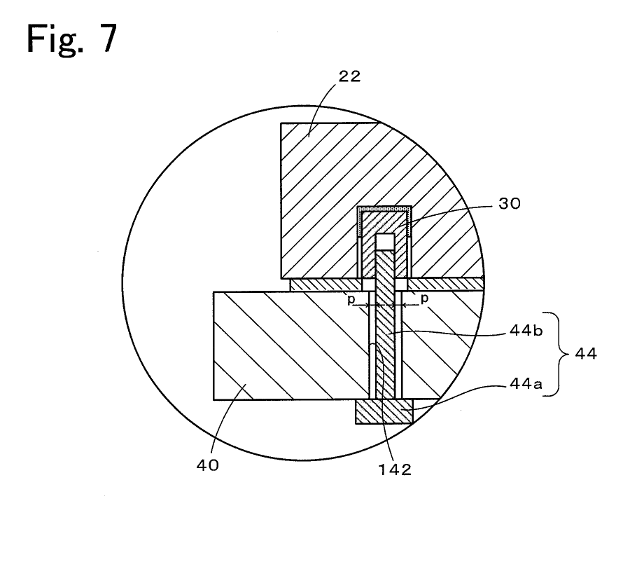

In the above-described embodiment, the through hole 42 of the cooling plate 40 has a step 42c, but the present invention is not particularly limited thereto. For example, as shown in FIG. 7, a through hole 142 having a straight shape and having no step may be provided, and when the screw shank 44b of the male screw 44 is screwed to the female threaded terminal 30 of the electrostatic chuck 22, the screw head 44a may be in contact with the lower surface of the cooling plate 40. When the cooling plate 40 expands and contracts relative to the electrostatic chuck 22, the screw head 44a can slide on the lower surface of the cooling plate 40, and the screw shank 44b can move in the through hole 142 in the left-right direction in FIG. 7, so that the electrostatic chuck 22 is not broken. Therefore, according to the configuration of FIG. 7, the same effect as in the above-described embodiment can be obtained.

In the above-described embodiment, a washer or a spring may be interposed between the screw head 44a and the step 42c. This prevents the screwed state between the female threaded terminal 30 and the male screw 44 from loosening. Similarly, a washer or a spring may be interposed between the nut 144 and the step 42c in FIG. 6 or between the screw head 44a and the lower surface of the cooling plate 40 in FIG. 7.

In the above-described embodiment, the heat conductive sheet 36 does not have adhesiveness, but may have adhesiveness as needed. In that case, it is preferable that the heat conductive sheet 36 have such elasticity that it is not peeled off or broken by the thermal stress caused by the difference in thermal expansion between the electrostatic chuck 22 and the cooling plate 40.

In the above-described embodiment, the electrostatic chuck 22 includes both the electrostatic electrode 24 and the heater electrode 26, but it may include either of them.

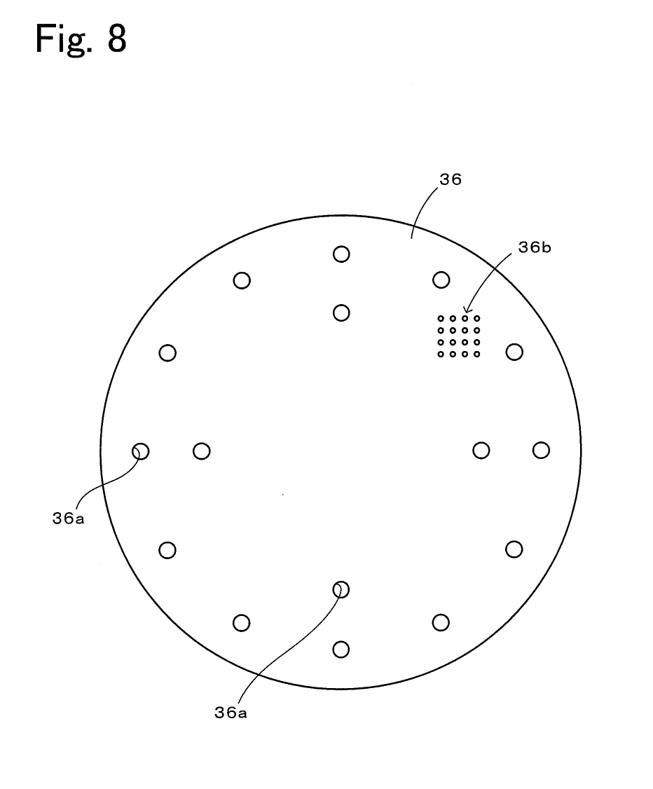

In the above-described embodiment, the heat conductive sheet 36 may be partially trimmed. FIG. 8 is a plan view of a heat conductive sheet 36 having a trimming region 36b. A plurality of small holes are provided in the trimming region 36b. This makes it possible to locally control heat removal from the electrostatic chuck 22 (ceramic plate) and to easily adjust the heat uniformity according to the actual use environment. Therefore, it is possible to realize a highly uniform temperature electrostatic chuck heater 20.

In the above-described embodiment, an O-ring or a metal seal may be disposed on the outermost periphery of the heat conductive sheet 36 in order to ensure the sealing characteristics under a high vacuum environment and to prevent corrosion of the heat conductive sheet.

This application claims the priority of Japanese Patent Application No. 2016-166086, filed on Aug. 26, 2016, the entire contents of which are incorporated herein by reference in their entirety.

What is claimed is:

1. A wafer mounting table comprising:
a ceramic plate having a wafer mounting surface and having at least one of an electrostatic electrode and a heater electrode built therein;
a metal plate arranged on a surface of the ceramic plate opposite to the wafer mounting surface;
a threaded terminal made of a low thermal expansion coefficient metal and joined to a recess provided in the surface of the ceramic plate opposite to the wafer mounting surface by a bonding layer including ceramic fine particles and a hard solder; and
a screw member inserted into a through hole penetrating the metal plate and screwed to the threaded terminal to fasten the ceramic plate and the metal plate together,
wherein in a state in which the threaded terminal and the screw member are screwed together, a play is provided in a direction in which the metal plate is displaced relative to the ceramic plate due to the difference in thermal expansion.

2. The wafer mounting table according to claim 1, further comprising a non-adhesive heat conductive sheet between the ceramic plate and the metal plate.

3. The wafer mounting table according to claim 1,
wherein the ceramic fine particles are fine particles whose surfaces are coated with a metal, and
wherein the hard solder contains Au, Ag, Cu, Pd, Al or Ni as a base metal.

4. The wafer mounting table according to a claim 1,
wherein the ceramic plate is made of AlN or Al₂O₃,
wherein the metal plate is made of Al or Al alloy; and
wherein the low thermal expansion coefficient metal is one kind selected from the group consisting of Mo, W, Ta, Nb and Ti, an alloy containing the one kind of metal, or Kovar.

5. The wafer mounting table according to claim 1,
wherein the coefficient of linear thermal expansion of the threaded terminal is within a range of ±25% of the coefficient of linear thermal expansion of the ceramic plate.
